(19) United States
(12) Patent Application Publication
(10) Pub. No.: US 2024/0235214 A9
(43) Pub. Date: Jul. 11, 2024

(54) EQUALIZATION CONTROL DEVICE FOR BATTERY

(71) Applicant: TOYOTA JIDOSHA KABUSHIKI KAISHA, Toyota-shi (JP)

(72) Inventor: Kohei TAKAHASHI, Toyota-shi (JP)

(73) Assignee: TOYOTA JIDOSHA KABUSHIKI KAISHA, Toyota-shi (JP)

(21) Appl. No.: 18/448,207

(22) Filed: Aug. 11, 2023

(30) Foreign Application Priority Data
Oct. 21, 2022 (JP) 2022-169124

(51) Int. Cl. H02J 7/00; B60L 58/22; G01R 31/388

(52) U.S. Cl. CPC H02J 7/0016; B60L 58/22; G01R 31/388; H02J 7/0049

(57) ABSTRACT

The control unit includes: when an absolute value of a difference between a full charge capacity of a 1 cell and a full charge capacity of a 2 cell is equal to or larger than a 1 threshold value, equalization is performed so that an absolute value of a difference between a charge rate of a 1 cell and a charge rate of a 2 cell at the time of full charge is less than a 2 threshold value, and when an absolute value of a difference between a voltage of a 1 cell and a voltage of a 2 cell is equal to or larger than a 3 threshold value, equalization is performed so that an absolute value of a difference between a voltage of a 1 cell and a voltage of a 2 cell becomes less than a 3 threshold value.

### CROSS-REFERENCE TO RELATED APPLICATION

This application claims priority to Japanese Patent Application No. 2022-169124 filed on Oct. 21, 2022, incorporated herein by reference in its entirety.

### BACKGROUND

### 1. Technical Field

The present disclosure relates to an equalization control device for controlling a battery (an assembled battery) constituted by a plurality of battery cells.

### 2. Description of Related Art

Japanese Unexamined Patent Application Publication No. 2020-068639 (JP 2020-068639 A) discloses a technique for equalizing a plurality of battery cells in a battery (an assembled battery) constituted by a plurality of battery cells having an SOC-OCV characteristic curve with a “flat area” in which a change rate of an Open Circuit Voltage (OCV) with respect to a State Of Charge (SOC) is equal to or less than a predetermined value. In the technique described in JP 2020-068639 A, after the state of the battery is shifted to a “non-flat area” other than the flat area by performing a charge rate lowering process or a charge rate raising process, equalization of a plurality of battery cells based on the open circuit voltage is performed in the non-flat area.

### SUMMARY

When equalization of a plurality of battery cells based on an open circuit voltage is performed in a “low SOC area”, which is an area of a lower charge rate among the non-flat area, the battery cells having small full charge capacities quickly reach a high charge rate in the charging process after the completion of equalization depending on the degree of variations in the full charge capacities in the plurality of battery cells, thereby increasing the voltage difference between the battery cells having small full charge capacities and the battery cells having large full charge capacities, and there is a possibility that the equalization needs to be performed again.

The present disclosure has been made in view of the above problem, and an object of the present disclosure is to provide an equalization control device capable of suppressing an increase in a voltage difference between a plurality of battery cells due to a charging process of the battery cells performed after completion of equalization, even when equalization of a plurality of battery cells is performed in a low SOC area.

In order to solve the above issue, an aspect of the technique of the present disclosure is an equalization control device for equalizing a plurality of battery cells for a battery including the battery cells and having an SOC-OCV characteristic curve with a flat area in which a change rate of an open circuit voltage with respect to a charge rate is equal to or lower than a predetermined value. The equalization control device includes: an acquisition unit for acquiring values of full charge capacities and voltages of a first cell and a second cell included in the battery cells; and a control unit for controlling equalization of the battery cells based on the values acquired by the acquisition unit. When an absolute value of a difference between a full charge capacity of the first cell and a full charge capacity of the second cell is equal to or greater than a first threshold, the control unit performs equalization such that an absolute value of a difference between a charge rate of the first cell and a charge rate of the second cell at a time of full charge is less than a second threshold. When the absolute value of the difference between the voltage of the first cell and the voltage of the second cell is equal to or greater than a third threshold, the control unit performs equalization such that an absolute value of a difference between the voltage of the first cell and the voltage of the second cell is less than the third threshold.

According to the equalization control device for the battery of the present disclosure, even when the equalization of the plurality of battery cells is performed in the low SOC area, it is possible to suppress the voltage difference between the plurality of battery cells from increasing due to the charging process of the battery cells performed after the completion of the equalization.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating a schematic configuration of a power supply system including an equalization control device according to an embodiment of the present disclosure;

FIG. 2 is a diagram showing an exemplary SOC-OCV profile of an iron phosphate-based lithium-ion battery; and

FIG. 3 is a processing flowchart of equalization control of a battery executed by the equalization control device.

### DETAILED DESCRIPTION OF EMBODIMENTS

The equalization control device controls an equalization process to be performed on a battery having a flat area in a SOC-OCV property curve composed of a plurality of battery cells based on a full charge capacity and a voltage of two or more battery cells to be equalized. Only the equalization process of the battery cells in the low SOC range can suppress the voltage-difference enlargement between the plurality of battery cells. Hereinafter, an embodiment of the present disclosure will be described in detail with reference to the drawings.

### Embodiment

### Configuration

FIG. 1 is a block diagram illustrating a schematic configuration of a power supply system 1 including an equalization control device 50 according to an embodiment of the present disclosure. The power supply system 1 illustrated in FIG. 1 includes a first battery 10, a DC-DC converter 20, a second battery 30, a plurality of in-vehicle devices 40, and the equalization control device 50 of the present embodiment.

The power supply system 1 shown in FIG. 1 can be mounted on a vehicle. In the following embodiments, the control of the equalization control device 50 according to the present embodiment will be described by exemplifying cases in which the power supply system 1 is mounted in hybrid electric vehicle (HEV), plug-in hybrid electric vehicle (PHEV), and battery electric vehicle (BEV) that use an electric motor as a power source.

The first battery 10 is a high-voltage battery for supplying electric power to an electric motor (not shown) and DC-DC converters 20. A typical first battery 10 mounted on a vehicle is, for example, a driving battery. The first battery 10 may be configured to acquire power from an external power source via a plug-in charger (not shown) connectable to the external power source. A secondary battery such as a lithium ion battery configured to be chargeable and dischargeable is used for the first battery 10.

DC-DC converters 20 connect the first battery 10, the second battery 30, and the plurality of in-vehicle devices 40. DC-DC converters 20 supply the electric power of the first battery 10 to the second battery 30 and the plurality of in-vehicle devices 40. When the power is supplied, DC-DC converters 20 may convert the high voltage of the first battery 10, which is the inputted voltage, into a predetermined low voltage and output the converted high voltage.

The second battery 30 is a low-voltage battery that charges electric power outputted from DC-DC converters 20 and discharges electric power stored therein. A typical second battery 30 mounted on the vehicle is, for example, an auxiliary battery. The second battery 30 of the present embodiment is a battery pack composed of a plurality of battery cells. The second battery 30 is typically configured by connecting a plurality of battery cells in series. Further, the second battery 30 may be configured by connecting two or more cell blocks in which several battery cells are connected in parallel in series.

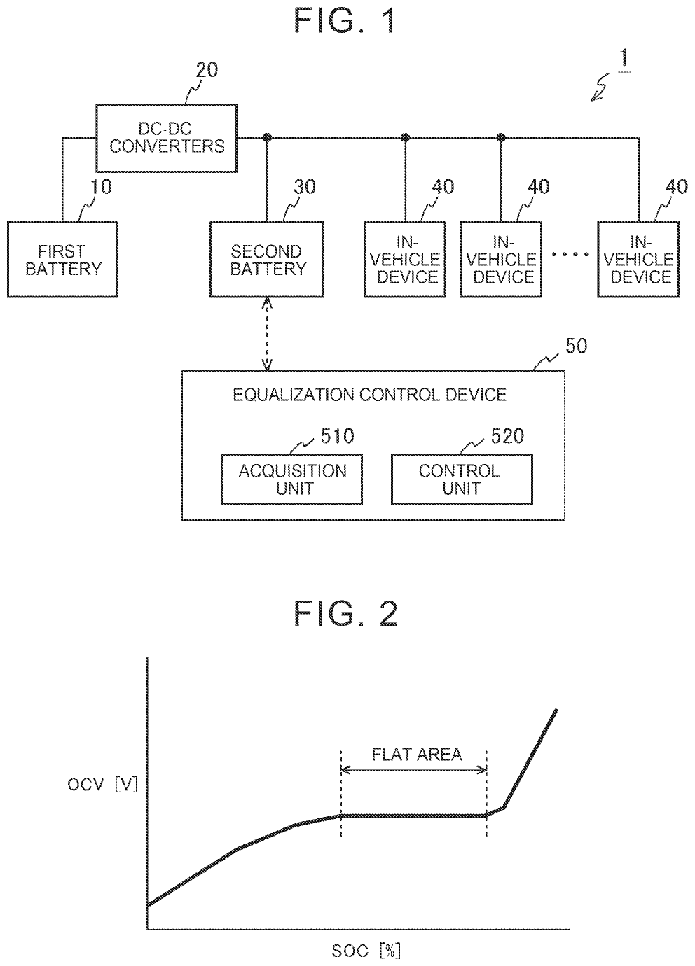

A battery having a flat region is used for each battery cell of the second battery 30. This flat region is a region in which the absolute value of the rate of change of the open circuit voltage OCV with respect to the charge rate SOC is equal to or less than a predetermined value in SOC-OCV property curve indicating the relation between the charge rate SOC of the battery and the open circuit voltage OCV. The predetermined value is a value determined based on the specifications of the battery or the like. Examples of the battery having a flat area include an iron phosphate-based lithium-ion battery (LFP battery). FIG. 2 shows an exemplary SOC-OCV profile of an iron phosphate-based lithium-ion battery.

The plurality of in-vehicle devices 40 are various devices mounted on vehicles that operate with electric power outputted from DC-DC converters 20 and electric power of the second battery 30. The plurality of in-vehicle devices 40 include, for example, actuators such as motors and solenoids, lights such as headlamps and indoor lights, air conditioners such as heaters and coolers, steering, braking, and electronic control unit (ECU) such as automated driving and advanced driving support).

The equalization control device 50 includes an acquisition unit 510 and a control unit 520. The equalization control device 50 controls the second battery 30. The equalization control device 50 may typically be configured as an electronic control unit (ECU) including a processor, memories, input/output interfaces, and the like. The electronic control unit realizes all or a part of the functions performed by the acquisition unit 510 and the control unit 520 by the processor reading and executing a program stored in the memory.

The acquisition unit 510 acquires the states of the plurality of battery cells constituting the second battery 30. Examples of the state of the battery cell include values of a full charge capacity and a voltage. The voltage of the battery cell is a voltage value between the positive electrode terminal and the negative electrode terminal. The voltage of the battery cell can be acquired through a detection element such as a voltage sensor provided in the battery cell. The full charge capacity of the battery cell can be acquired when the second battery 30 is inspected or replaced in, for example, a dealer or a maintenance factory, or can be acquired by using a well-known technique for measuring or estimating the full charge capacity.

The control unit 520 controls a process of equalizing variations in voltage and charging rate occurring between the plurality of battery cells based on the states of the plurality of battery cells constituting the second battery 30 acquired by the acquisition unit 510. Voltage variations among a plurality of battery cells occur due to variations in the self-discharge amount of each battery cell or the like. When a voltage varies among a plurality of battery cells, deterioration of a specific battery cell accelerates or the amount of available energy decreases. For this reason, the control unit 520 discharges a battery cell having a high voltage as necessary, lowers the voltage, and aligns the voltage with the voltage of another battery cell, thereby avoiding these effects.

### Control

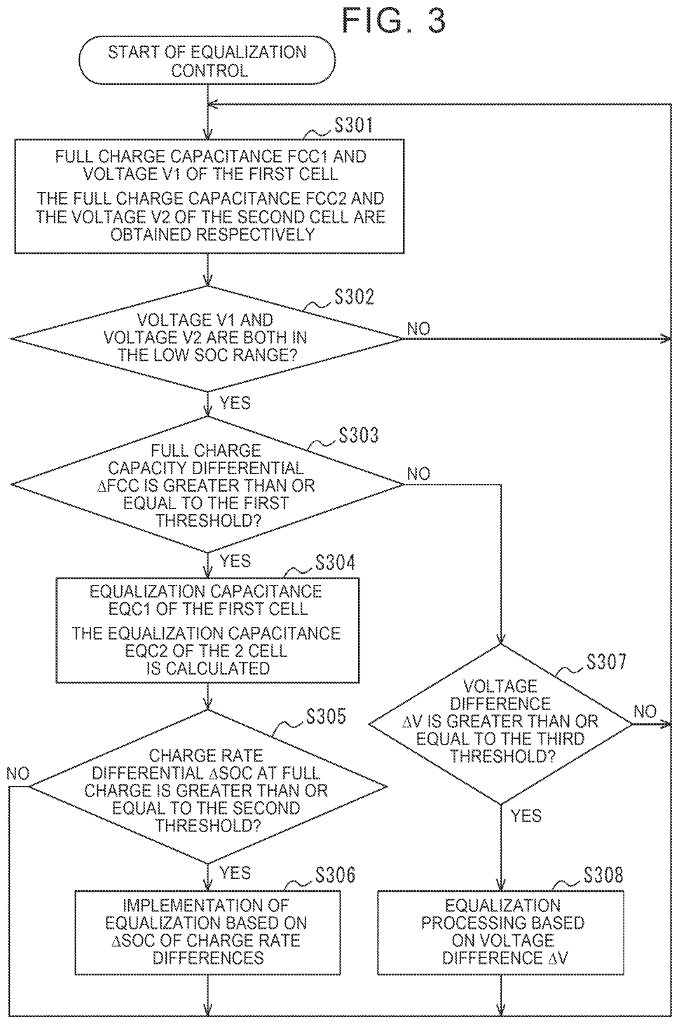

Next, with further reference to FIG. 3, control performed by the equalization control device 50 according to an embodiment of the present disclosure will be described. FIG. 3 is a flowchart illustrating a processing procedure of equalization control performed on a plurality of battery cells constituting the second battery 30 executed by the equalization control device 50.

Note that FIG. 3 illustrates an example of control for equalizing cells among the first cell and the second cell among the plurality of battery cells constituting the second battery 30. However, equalization control between cells intended for three or more battery cells can also be performed in a similar manner according to the procedure of FIG. 3.

The equalization control of the battery cells illustrated in FIG. 3 is started at a timing that does not affect the operation of the plurality of in-vehicle devices 40. As an example, the equalization control of the battery cells is started at a timing when the power supply of the vehicle is turned off (for example, at a timing when the ignition switch is switched from on to off).

### S301

The acquisition unit 510 of the equalization control device 50 obtains the full charge capacity FCC1 of the first cell, the voltage V1 of the first cell, the full charge capacity FCC2 of the second cell, and the voltage V2 of the second cell, respectively.

When the acquisition unit 510 acquires the full charge capacitance and the voltage of the cells, the process proceeds to S302.

### S302

The control unit 520 of the equalization control device 50 determines whether both the voltage V1 of the first cell and the voltage V2 of the second cell acquired by the acquisition unit 510 are in the low SOC area where the charge rate is lower than the flat area on SOC-OCV property curve. That is, it is determined whether the voltage V1 of the first cell and the voltage V2 of the second cell are both lower than the lower limit voltage of the flat area. The lower limit for determining that the battery is in the low SOC range is determined in advance based on the specifications of the second battery 30 and the like.

When the control unit 520 determines that both the voltage V1 of the first cell and the voltage V2 of the second cell are in the low SOC range (S302, Yes), the process proceeds to S303. On the other hand, when the control unit 520 determines that both the voltage V1 of the first cell and the voltage V2 of the second cell are not in the low SOC range (S302, No), the process proceeds to S301 without performing the equalization process.

### S303

The control unit 520 of the equalization control device 50 determines whether or not the full charge capacity difference ΔFCC between the first cell and the second cell is equal to or greater than the first threshold. The full charge capacity difference ΔFCC is an absolute value of a difference between the full charge capacity FCC1 of the first cell and the full charge capacity FCC2 of the second cell (ΔFCC=|FCC1−FCC2|). This determination is made to determine whether equalization needs to be performed between the first cell and the second cell. Therefore, the first threshold value is appropriately set based on the characteristics of the second battery 30, the performance required for the vehicle, and the like from the viewpoint of suppressing the deterioration progress of the second battery 30 and the like.

If the control unit 520 determines that the full charge capacity difference ΔFCC between the first cell and the second cell is equal to or greater than the first threshold (S303, Yes), the process proceeds to S304. On the other hand, when the control unit 520 determines that the full charge capacity difference ΔFCC between the first cell and the second cell is less than the first threshold (S303, No), the process proceeds to S307.

### S304

The control unit 520 of the equalization control device 50 calculates the equalization capacitance EQC1 of the first cell and the equalization capacitance EQC2 of the second cell, respectively. The equalization capacitance EQC1 [Ah] of the first cell can be derived by the following equation [1] based on the full charge capacitance FCC1 [Ah] of the first cell and the charge rate SOC_V1 [%] derived from the voltage V1 [V] by SOC-OCV property curve. Further, the equalization capacitance EQC2 [Ah] of the second cell can be derived by the following equation [2] based on the full charge capacitance FCC2 [Ah] of the second cell and the charge rate SOC_V2 [%] derived from the voltage V2 [V] by SOC-OCV property curve.

EQC1=(100−SOC_V1)×FCC1 [1]

EQC2=(100−SOC_V2)×FCC2 [2]

When the equalization capacitance of the cells is calculated by the control unit 520, the process proceeds to S305.

### S305

The control unit 520 of the equalization control device 50 determines (estimates) whether or not the charge rate difference ΔSOC between the first cell and the second cell is equal to or greater than the second threshold value in the case where the charging process of bringing the current second battery 30 into the fully charged state is performed. The charge rate difference ΔSOC is a difference in charge rate between one cell that has been fully charged due to a variation in the battery cell and the other cell that does not reach the full charge state, and can be derived based on the equalization capacitance EQC1 of the first cell and the equalization capacitance EQC2 of the second cell.

For example, when the first cell is the full charge capacity FCC1=“30 Ah” and SOC_V1=“10%”, the equalization capacity EQC1=“27.0 Ah” of the first cell is calculated by the above equation [1]. On the other hand, when the second cell has the full charge capacity FCC1=“29 Ah” and SOC_V1=“20%”, the equalization capacity EQC2=“23.2 Ah” of the second cell is calculated by the above equation [2]. When the second battery 30 including the first cell and the second cell in the configuration is charged, the second cell is fully charged by 100% at the time when 23.2 Ah is supplied to the second cell, but the first cell is only about 87% (=10+23.2/30×100) at 23.2 Ah power supply, resulting in a charge rate difference ΔSOC≈“13%” between the first cell and the second cell. The second threshold value is set depending on how much the charge rate difference ΔSOC is allowed.

When the control unit 520 determines that the charge rate difference ΔSOC between the first cell and the second cell at the time of full charge is equal to or greater than the second threshold value (S305, Yes), the process proceeds to S306. On the other hand, when the control unit 520 determines that the charge rate difference ΔSOC between the first cell and the second cell at the time of full charge is less than the second threshold (S305, No), the process proceeds to S301 without performing the equalization process.

### S306

The control unit 520 of the equalization control device 50 performs the equalization process based on the charge rate difference ΔSOC between the first cell and the second cell at the time of full charge. Specifically, the control unit 520 discharges the electric power accumulated in the cell having the lower equalization capacitance so that the equalization capacitance EQC1 of the first cell and the equalization capacitance EQC2 of the second cell coincide with each other.

For example, when the equalization capacitance EQC1 of the first cell is “27.0 Ah” and the equalization capacitance EQC2 of the second cell is “23.2 Ah”, the equalization capacitance EQC2 of the second cell is equalized to the same “27.0 Ah” as the equalization capacitance EQC1 of the first cell by discharging the power of the second cell by 3.8 Ah. Note that the power may be charged to the first cell by a 3.8 Ah amount, and the equalization capacitance EQC1 of the first cell may be aligned to the same “23.2 Ah” as the equalization capacitance EQC2 of the second cell.

When the control unit 520 performs the equalization process based on the charge rate difference ΔSOC between the first cell and the second cell at the time of full charge, the process proceeds to S301.

### S307

The control unit 520 of the equalization control device 50 determines whether the voltage difference ΔV between the first cell and the second cell is equal to or greater than a third threshold value. The voltage difference ΔV is an absolute value of a difference between the voltage V1 of the first cell and the voltage V2 of the second cell (ΔV=|V1−V2|). This determination is made to determine whether equalization needs to be performed between the first cell and the second cell. Therefore, the third threshold value is appropriately set based on the characteristics of the second battery 30, the performance required for the vehicle, and the like from the viewpoint of suppressing the deterioration progress of the second battery 30 and the like.

When the control unit 520 determines that the voltage difference ΔV between the first cell and the second cell is equal to or greater than the third threshold (S307, Yes), the process proceeds to S308. On the other hand, when the control unit 520 determines that the voltage difference ΔV between the first cell and the second cell is less than the third threshold (S307, No), the process proceeds to S301 without performing the equalization process.

### S308

The control unit 520 of the equalization control device 50 performs the equalization process on the basis of the voltage difference ΔV between the first cell and the second cell. Specifically, the control unit 520 discharges the electric power accumulated in the cell having the higher voltage so that the voltage V1 of the first cell and the voltage V2 of the second cell coincide with each other.

For example, when the voltage V1 of the first cell is “3.2V” and the voltage V2 of the second cell is “3.3V”, the power of the second cell is discharged until the voltage V2 drops to 3.2V, and the voltage V2 of the second cell is aligned with the same “3.2V” as the voltage V1 of the first cell. Note that the first cell may be charged with electric power to align the voltage V1 of the first cell with the same “3.3V” as the voltage V2 of the second cell.

When the equalization process based on the voltage difference ΔV between the first cell and the second cell is performed by the control unit 520, the process proceeds to S301.

### Operations and Effects

As described above, according to the equalization control device 50 of the embodiment of the present disclosure, the equalization process based on the full charge capacity and voltage of two or more battery cells to be equalized is appropriately performed on the second battery 30 having the flat area in SOC-OCV property curve composed of a plurality of battery cells.

Specifically, when the full charge capacity difference ΔFCC between the first cell and the second cell is equal to or greater than the first threshold value, the equalization process is performed such that the charge rate difference ΔSOC between the first cell and the second cell at the time of full charge is less than the second threshold value.

When the voltage difference ΔV between the first cell and the second cell is equal to or greater than the third threshold value, the equalization process is performed such that the voltage difference ΔV between the first cell and the second cell is less than the third threshold value.

With such control, even when the equalization processing of the plurality of battery cells is performed in the low SOC area, it is possible to suppress the voltage-difference between the plurality of battery cells from increasing due to the charging processing of the battery cells performed after the completion of the equalization processing.

Although an embodiment of the present disclosure has been described above, the present disclosure can be regarded as not only the above-described equalization control device but also an equalization control method executed by an equalization control device including a processor and a memory, a control program of the equalization control method, a non-transitory computer-readable recording medium storing the control program, or a vehicle equipped with the equalization control device.

The battery equalization control device of the present disclosure can be used in a case where a battery constituted by a plurality of battery cells is controlled.

What is claimed is:

1. An equalization control device for equalizing a plurality of battery cells for a battery including the battery cells and having an SOC-OCV characteristic curve with a flat area in which a change rate of an open circuit voltage with respect to a charge rate is equal to or lower than a predetermined value, the equalization control device comprising:
an acquisition unit for acquiring values of full charge capacities and voltages of a first cell and a second cell included in the battery cells; and
a control unit for controlling equalization of the battery cells based on the values acquired by the acquisition unit, wherein in a case where a voltage of the first cell and a voltage of the second cell are lower than a lower limit voltage of the flat area, when an absolute value of a difference between a full charge capacity of the first cell and a full charge capacity of the second cell is equal to or greater than a first threshold, the control unit performs equalization such that an absolute value of a difference between a charge rate of the first cell and a charge rate of the second cell at a time of full charge is less than a second threshold.

2. The equalization control device according to claim 1, wherein in a case where the voltage of the first cell and the voltage of the second cell are lower than the lower limit voltage of the flat area, when the absolute value of the difference between the full charge capacity of the first cell and the full charge capacity of the second cell is less than the first threshold, the control unit performs equalization such that an absolute value of a difference between the voltage of the first cell and the voltage of the second cell is less than a third threshold.
